(19) United States
(12) Patent Application Publication
(10) Pub. No.: US 2014/0131716 A1
(43) Pub. Date: May 15, 2014

(54) MEMORY DEVICE AND METHOD FOR FABRICATING THE SAME

(71) Applicant: NATIONAL APPLIED RESEARCH LABORATORIES, Taipei City (TW)

(72) Inventors: Jia-Min Shieh, Hsinchu (TW); Yu-Chung Lien, Taoyuan County (TW); Wen-Hsien Huang, Hsinchu (TW); Chang-Hong Shen, Hsinchu (TW); Min-Cheng Chen, Hsinchu (TW); Ci-Ling Pan, Hsinchu (TW)

(73) Assignee: NATIONAL APPLIED RESEARCH LABORATORIES, Taipei City (TW)

(21) Appl. No.: 13/744,594

(22) Filed: Jan. 18, 2013

(30) Foreign Application Priority Data
Nov. 12, 2012 (TW) 101142092

(51) Int. Cl. H01L 29/792

(52) U.S. Cl. CPC H01L 29/792; Y10S 977/774; B82Y 99/00
USPC 257/66; 257/324

(57) ABSTRACT

A memory device comprises a substrate, a tunnel oxide layer, a charge trapping layer, a block oxide layer, a plurality of conductive quantum dots, a metal gate and a source/drain structure. The tunnel oxide layer is disposed on the substrate and has a thickness substantially less than or equal to 2 nm. The charge trapping layer is disposed on the tunnel oxide layer. The quantum dots are embedded in the charge trapping layer. The block oxide layer is disposed on the charge trapping layer. The metal gate essentially consisting of aluminum (Al), copper (Cu), tantalum nitride (TiN), titanium nitride (TaN), aluminum-silicon-copper (Al—Si—Cu) alloys or the arbitrary combinations thereof is disposed on the block oxide layer. The source/drain structure is disposed in the substrate.

### FIELD OF THE INVENTION

The present invention relates to a memory device and the method for fabricating the same, and more particularly to a memory device with a metal gate and the fabricating method thereof.

### BACKGROUND OF THE INVENTION

Non-volatile memory cells are widely used because they can store data even when the power supply is cut off. Generally, non-volatile memory cells can be sub-classified into two types, floating-gate structure and SONOS structure. The floating-gate structure utilizes source side injection (SSI) or tunneling effect leading hot electrons stored in the floating gate.

However, the application of the floating-gate structure is increasingly difficult day after day, because of the hot electrons punching through along the select gate channel as the source-drain channel length shrinks. In comparison with the floating-gate structure, the SONOS structure which also leads hot electrons stored in a silicon nitride layer can be manufactured in a smaller critical size by simpler processes, by which functions of multi-level storage are provided to overcome the drain-induced turn-on effect. Therefore, there is a prevailing tendency today to replace the floating-gate structure with the SONOS structure.

However, for the purpose of performance improvement, there are still challenges to the industry in terms of improving the programming and erasing (P/E) speed, decreasing the operation voltage and improving the reliability of the SONOS structure.

Therefore, there is a need of providing an improved memory device and the fabricating method thereof to obviate the drawbacks encountered from the prior art.

### SUMMARY OF THE INVENTION

In accordance with an aspect, the present invention provides a memory device comprises a substrate, a tunnel oxide layer, a charge trapping layer, a block oxide layer, a plurality of conductive quantum dots, a metal gate and a source/drain structure. The tunnel oxide layer is disposed on the substrate and has a thickness substantially less than or equal to 2 nm. The charge trapping layer is disposed on the tunnel oxide layer. The quantum dots are embedded in the charge trapping layer. The block oxide layer is disposed on the charge trapping layer. The metal gate essentially consisting of aluminum (Al), copper (Cu), tantalum nitride (TaN), titanium nitride (TiN), aluminum-silicon-copper (Al—Si—Cu) alloys or the arbitrary combinations thereof is disposed on the block oxide layer. The source/drain structure is disposed in the substrate.

In one embodiment of the present invention, the substrate is a silicon substrate or a silicon-on-insulator (SOI) substrate.

In one embodiment of the present invention, the tunnel oxide layer is a silicon oxide layer, and the charge trapping layer is a silicon nitride layer.

In one embodiment of the present invention, the block oxide layer is a metal oxide layer or a silicon oxide layer.

In one embodiment of the present invention, the conductive quantum dots are selected from a group consisting of a plurality of semiconductor quantum dots, a plurality of metal quantum dots and the arbitrary combinations thereof.

In one embodiment of the present invention, the conductive quantum dots are silicon quantum dots having an average particle diameter substantially ranging from 2 nm to 4 nm.

In one embodiment of the present invention, the memory device further comprises a channel layer disposed between the substrate and the tunnel oxide layer and an isolation layer disposed between the substrate and the channel layer. In one embodiment of the present invention, the channel layer comprises polycrystalline silicon and the isolation layer is a silicon oxide layer.

In one embodiment of the present invention, the memory device is a three dimensional stacked memory device, an ultra thin channel device, a nano-wire memory device, a carbon-nano-tube memory device or a fin field effect transistor device.

In accordance with another aspect, the present invention provides a method for fabricating a memory device, the method comprises steps as follows: A tunnel oxide layer, a charge trapping layer having a plurality of quantum dots embed therein and a block oxide layer are formed on the substrate. A metal gate essentially consisting of Al, Cu, TiN, TaN, Al—Si—Cu alloys or the arbitrary combinations thereof is then formed on the block oxide layer. Subsequently, a source/drain structure is formed in the substrate, and a laser annealing process is then performed on the source/drain structure.

In one embodiment of the present invention, the laser annealing process is a laser spike annealing process using a laser having a peak power density of 2.1×10³ W/cm².

In accordance with another aspect, the present invention provides a memory device comprises a substrate, a tunnel oxide layer, a charge trapping layer, a block oxide layer, a plurality of conductive quantum dots, a metal gate and a source/drain structure. The tunnel oxide layer is disposed on the substrate and has a thickness substantially less than or equal to 2 nm. The charge trapping layer is disposed on the tunnel oxide layer. The quantum dots are embedded in the charge trapping layer. The block oxide layer is disposed on the charge trapping layer. The metal gate essentially consisting of aluminum (Al), copper (Cu), aluminum-silicon-copper (Al—Si—Cu) alloys or the arbitrary combinations thereof is disposed on the block oxide layer. The source/drain structure is disposed in the substrate.

In accordance with further another aspect, the present invention provides a memory device comprises a substrate, a tunnel oxide layer, a charge trapping layer, a block oxide layer, a plurality of conductive quantum dots, a metal gate and a source/drain structure. The tunnel oxide layer is disposed on the substrate. The charge trapping layer is disposed on the tunnel oxide layer. The quantum dots are embedded in the charge trapping layer. The block oxide layer is disposed on the charge trapping layer. The metal gate essentially consisting of aluminum (Al), copper (Cu), aluminum-silicon-copper (Al—Si—Cu) alloys or the arbitrary combinations thereof is disposed on the block oxide layer. The source/drain structure is disposed in the substrate.

In accordance with the aforementioned embodiments, a memory device and a method for fabricating the same are provided, wherein the memory device comprises a stacked structure including a metal gate, a block oxide layer, a charge trapping layer, a tunnel oxide layer and a channel, a plurality of conductive quantum dots embedded in the charge trapping layer and a source/drain structure formed in the substrate and activated by a laser annealing process.

By adopting the quantum dots in the memory device, superior electric characteristics, such as increased P/E speed, decreased operation voltage and the improved reliability, can be provided. In addition, using the laser annealing process to activate the source/drain structure can result in a low thermal budget for fabricating the memory device. Furthermore, the metal gate can shield the stacked structure (including a metal gate, a block oxide layer, a charge trapping layer, a tunnel oxide layer and a channel) from being damaged by the laser, and prevent the quantum dots from re-crystallization or deformation, whereby the performance of the memory device can be improved significantly.

### BRIEF DESCRIPTION OF THE DRAWINGS

The above objects and advantages of the present invention will become more readily apparent to those ordinarily skilled in the art after reviewing the following detailed descriptions and accompanying drawings, in which:

FIGS. 1A to 1B are schematic cross-sectional views illustrating a method for fabricating a nonvolatile memory (NVM) device, in accordance with one embodiment of the present invention;

FIGS. 2A and 2B are images of quantum dots embedded in a NVM device taken with a transmission electron microscope, in accordance with one embodiment of the present invention;

FIG. 3 is a curve diagram illustrating transfer characteristics of a NVM device before and after P/E conditions, in accordance with one embodiment of the present invention;

FIG. 4 is a curve diagram illustrating P/E characteristics of a NVM device, in accordance with one embodiment of the present invention;

FIG. 5 is a curve diagram illustrating normalized charge loss-charge retention time relationship of a metal-oxide-nitride-oxide-silicon (MONOS) memory device and a NVM device, in accordance with one embodiment of the present invention; and

FIG. 6 is a curve diagram illustrating threshold voltage-P/E cycles relationship of a MONOS memory device and a NVM device, in accordance with one embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

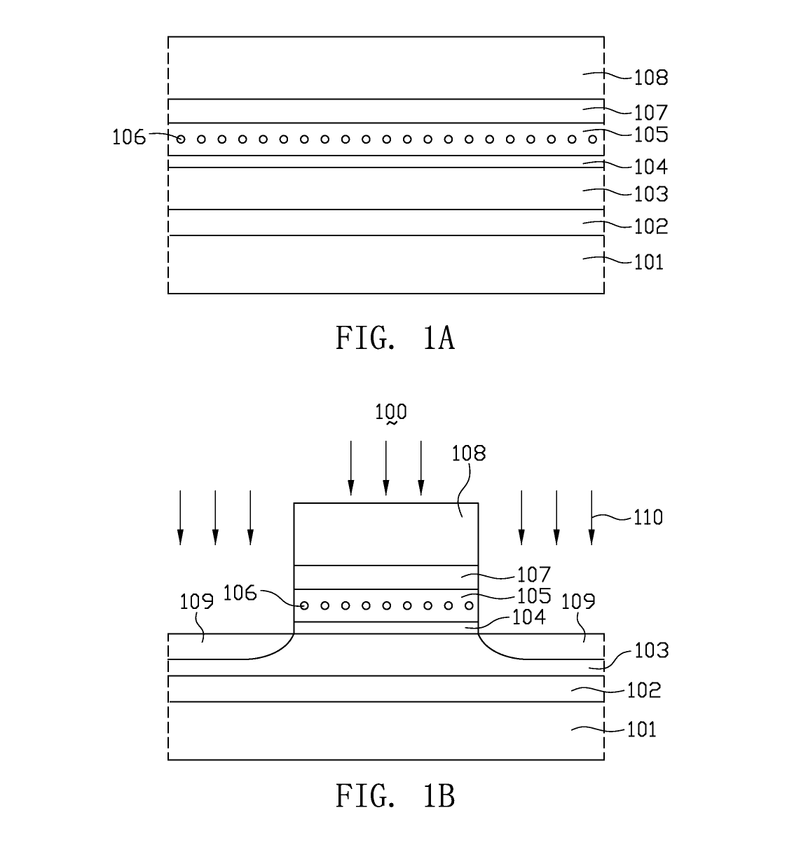

FIGS. 1A to 1B are schematic cross-sectional views illustrating a method for fabricating a nonvolatile memory (NVM) device 100, in accordance with one embodiment of the present invention. The method for fabricating the NVM device 100 comprises steps as follows: A substrate 101 is firstly provided and an isolation layer 102 is then formed on the substrate 101. In some embodiments of the present invention, the substrate 101 may be a semiconductor substrate, e.g. a silicon substrate or a silicon-on-insulator (SOI) substrate, and the isolation layer is a silicon oxide layer formed by a thermal oxidation process performed on the silicon substrate 101. In the present embodiment, the isolation layer has a thickness about 1,000 nm.

Next, a channel layer 103 is formed on the isolation layer 102. In some embodiments of the present invention, the channel layer 103 may be made of silicon, germanium, grapheme, other III-V compounds, such as indium nitride (InN) and gallium nitride (GaN), or the arbitrary combinations thereof. In the present embodiment, the channel layer 103 is a polycrystalline silicon layer, and the forming of the channel layer 103 comprises steps as follows:

An amorphous silicon film having a thickness about 1,000 nm is firstly deposited on the isolation layer 102 by a low pressure chemical vapor deposition (LPCVD) at 550° C. Subsequently, a sub-millisecond spike laser annealing process using neodymium-yttrium aluminum garnet (Nd-YAG) laser is performed at room temperature to form the polycrystalline silicon channel layer 103 having a grain size (average particle diameter) about 1 μm on the isolation layer 102. In some embodiments of the present invention, the Nd-YAG laser has a wavelength of 532 nm, a pulse width of 13 nanosecond (ns), a scanning speed of 25 cm/s and a beam size of 2.7 mm×60 μm.

After the channel layer 103 is formed, a tunnel oxide layer 104 is formed on thereon. In some embodiments of the present invention, the tunnel oxide layer 104 may be made of silicon oxide or other materials of high dielectric constant (k). In the present embodiment, the forming of the tunnel oxide layer 104 comprises steps of introducing nitrous oxide (N₂O) gas into a LPCVD furnace to form a silicon oxide layer having a thickness substantially equal or less than 2 nm on the channel layer 103.

Subsequently, a charge trapping layer 105 made of silicon nitride and having a plurality of quantum dots 106 embedded therein (also referred as quantum dots embedded nitride layer) is formed on the tunnel oxide layer 104 by a successive in situ deposition. In some embodiments of the present invention, the quantum dots 106 embedded in the charge trapping layer 105 are metal quantum dots, semiconductor quantum dots, such as silicon quantum dots, germanium quantum dots, silicon-germanium quantum dots, gallium quantum dots, arsenic quantum dots, indium quantum dots, gallium arsenide quantum dots, indium arsenide quantum dots or indium gallium arsenide quantum dots, or the combination thereof. In the present invention, the quantum dots 106 are silicon quantum dots (therein after referred as silicon quantum dots 106).

The forming of the charge trapping layer 105 that has the silicon quantum dots 106 embedded therein comprises steps as follows: Precursors comprising dichlorosilane (SiH₂Cl) and (NH₃) gases are introduced into a LPCVD furnace to form a silicon nitride layer having a thickness about 3 nm on the tunnel oxide layer 104. Subsequently, the air is evacuated from the LPCVD furnace, and SiH₂C is then reintroduced in to the vacuumed furnace for 60 seconds, so as to form a plurality of nanocrystals (silicon quantum dots 106) on the silicon nitride layer. Thereinafter, the air is evacuated from the LPCVD furnace, and the deposition process using SiH₂Cl and NH₃ as precursors is repeated again to form another silicon nitride layer having a thickness about 4 nm on the silicon nitride layer having the nanocrystals deposited thereon.

Next, a block oxide layer 107 having a thickness about 5 nm is formed on the charge trapping layer 105 by a low pressure chemical vapor deposition (LP-CVD) process. In some embodiments of the present invention, the block oxide layer 107 may be a silicon oxide layer. In some other embodiments of the present invention, the block oxide layer 107 may be made of materials including metal oxide, such as aluminum oxide (Al₂O₃), and the like.

A metal deposition process is then performed on the block oxide layer 107 to form a metal gate layer 108 with a thickness about 200 nm (see FIG. 1A). In some embodiments of the present invention, the metal gate layer 108 may essentially consist of Al, Cu, TiN, TaN, Al—Si—Cu alloys or the arbitrary combinations thereof. In the present embodiment, the metal gate layer 108 is made of Al—Si—Cu alloys.

After the metal gate layer 108 is formed a lithography/etching process is performed to pattern the metal gate layer 108, the block oxide layer 107, the charge trapping layer 105 and the tunnel oxide layer 104; and a plurality of successive ion implantation processes are carried out to form a source/drain structure 109 in the substrate 101. Subsequently, the source/drain structure 109 is activated by a laser annealing process, meanwhile the memory device 100 is completed (see FIG. 1B). In the present embodiment, the laser annealing process is a laser spike annealing process using a laser having a peak power density of 2.1×10³ W/cm².

Because the metal gate layer 108 exhibits higher light-reflection than nonmetal gate electrodes. For example, the metal gate layer 108 can reflect over 90% of the laser with a wavelength of 532 nm; however, merely 30% of the laser is reflected by a polycrystalline silicon gate electrode. Thus, the metal gate layer 108 can serves as a light shielding layer to protect the block oxide layer 107, the charge trapping layer 105 and the tunnel oxide layer 104 that are disposed beneath the metal gate layer 108 from the thermal damage and to prevent the quantum dots 106 from re-crystallization and deformation during the laser annealing process.

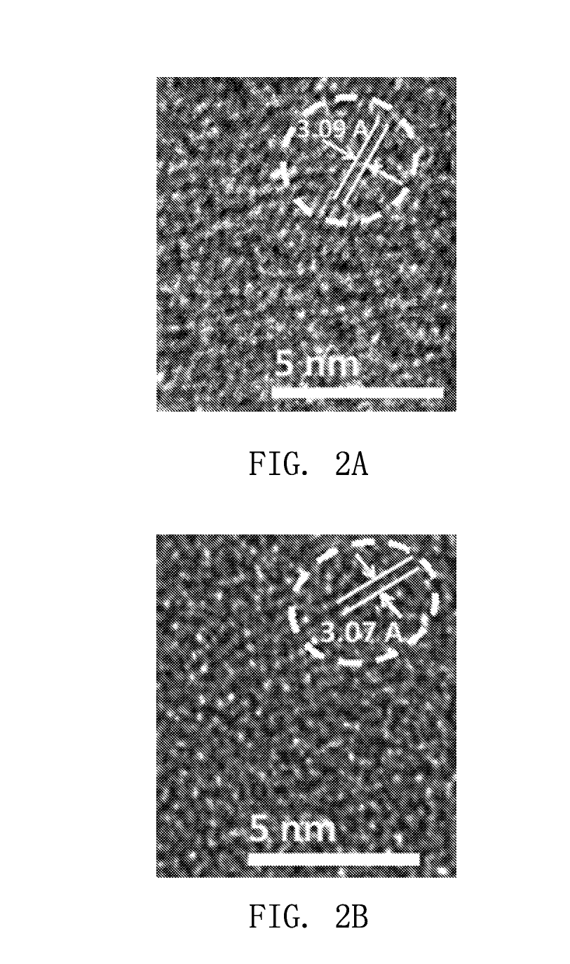

FIGS. 2A and 2B are images of quantum dots 106 embedded in a NVM device 100 taken with a transmission electron microscope, in accordance with one embodiment of the present invention. In FIGS. 2A and 2B, a plurality of silicon quantum dots 106 with a grain size ranging from 2 nm to 4 nm, preferably of 3.9 nm, embedded in the charge trapping layer 105 of the NVM device 100 (see FIG. 2A), and the spacing of the lattice plane along Si <111> surface is remained stable around 3.07 Å (see FIG. 2B) whether the laser annealing process is carried out or not. Apparently, re-crystallization and deformation does not occur among the quantum dots 106, and the adverse effect due to the laser annealing process is eliminated.

The reason may be that the pulse width adopted by the layer annealing is limited about sub-millisecond, few energy can passing through the metal gate layer 108 to cause the quantum dots 106 re-crystallization and deformation, nevertheless the laser spike annealing process may suddenly impose a peak power density to the metal gate layer 108.

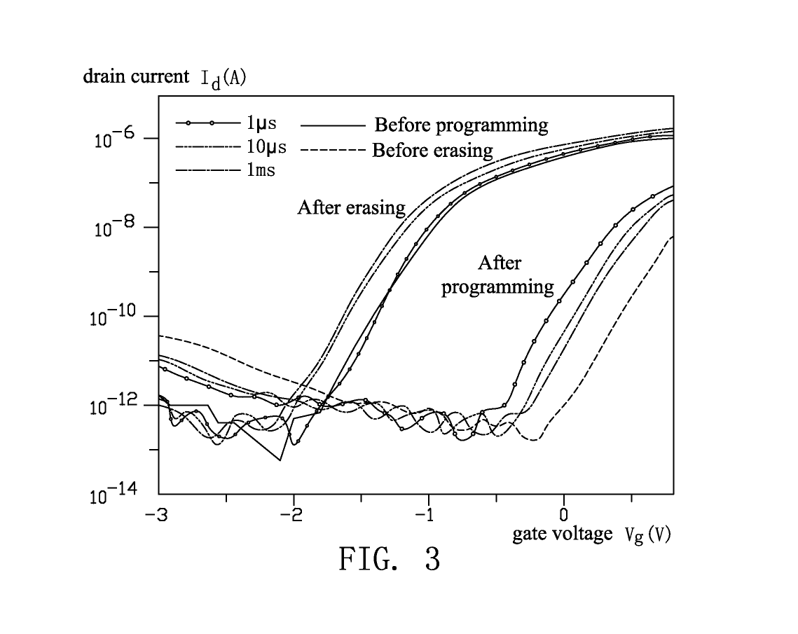

FIG. 3 is a curve diagram illustrating transfer characteristics of a NVM device 100 before and after P/E conditions, in accordance with one embodiment of the present invention. The X-axis indicates the gate voltage (V_{g}); the Y-axis indicates the drain current (I_{d}); and different curves indicate the transfer characteristics of the NVM device 100 while programmed and erased at different voltages (7 v or −7 v) within different pulse width of 1 microsecond (μs), 10 (ms) or 1 millisecond (ms) respectively.

Referring to the drain current-drain current relationship curves of FIG. 3, it is clear that the NVM device 100 has an ON/OFF current ratio substantially greater than 10⁵ and a sub-threshold swing substantially less than 0.19 V/decade, wherein the low sub-threshold swing characteristic can facilitate the memory-state diagnosis of program and erase (On and OFF) states. In addition, FIG. 3 dose not reveal any current gathering effect at low gate voltage. It means that the output characteristic of the NVM device 100 shows fairly lower parasitic resistance (Rp). In the present embodiment, the Rp of the NVM device 100 is of 3.07 kΩ-μm which is fairly lower than 12.14 kΩ-μm the Rp of a typical NVM device activated by a classical rapid thermal annealing (RTA) process. These results further demonstrate that the NVM device 100 has fairly good output characteristic.

It can also be observed that after programming and erasing at voltages of 7 V and −7 V with 1 μs pulse, the threshold voltage (ΔVₜₕ) of the NVM device 100 shifts 1.67 and 1.8 V, respectively, which is large enough for a typical sense amplifier to detect memory window of 0.5 V. It demonstrates that the NVM device 100 is fairly capable of multi-level storage.

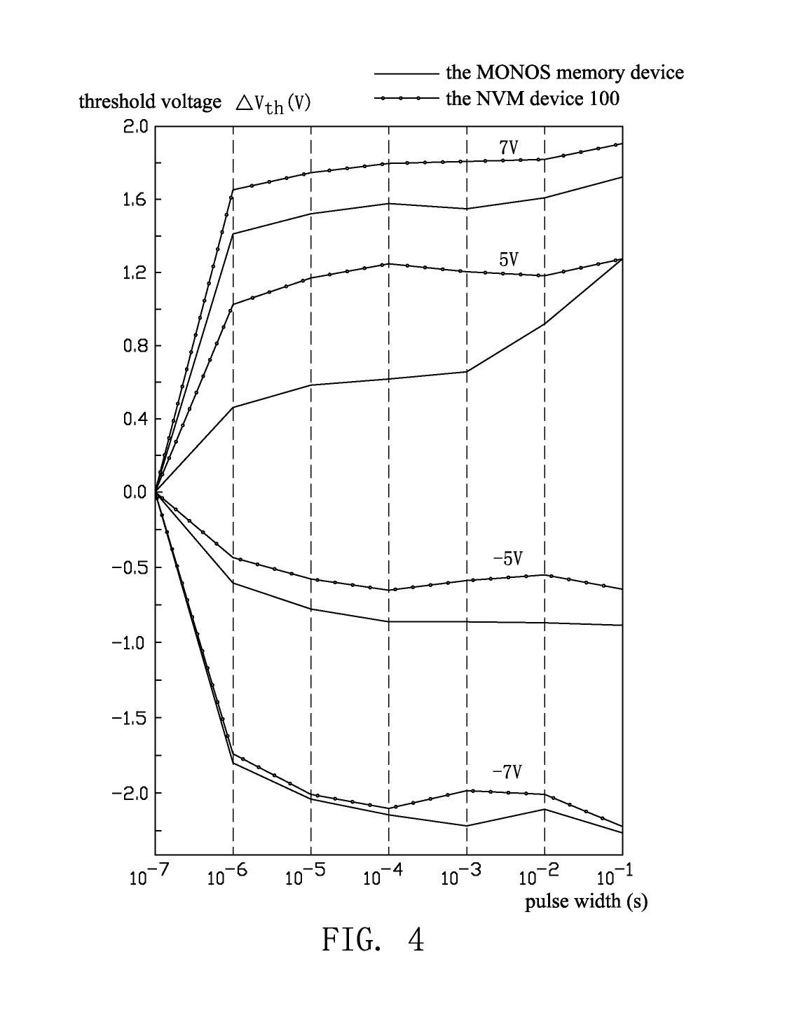

FIG. 4 is a curve diagram illustrating P/E speed characteristics of a NVM device 100, in accordance with one embodiment of the present invention. The X-axis indicates the pulse width (s); the Y-axis indicates the threshold voltage (ΔVₜₕ); and different curves indicate P/E speed characteristics of the NVM device 100 and a metal-oxide-nitride-oxide-silicon (MONOS) memory device that does not include any quantum dots operated at different voltages of ±5 v or ±7 v respectively by Fowler-Nordheim (F-N) injection.

In comparison with the MONOS memory device, during the program state, the P/E speed characteristics of the NVM device 100 reveal broader memory window under each applied voltages; and the erase speed of the NVM device 100 is substantially equal to that of the MONOS memory device. It demonstrates that the quantum dots 106 embedded in the charge trapping layer 105 can enhance the P/E speed of the NVM device 100.

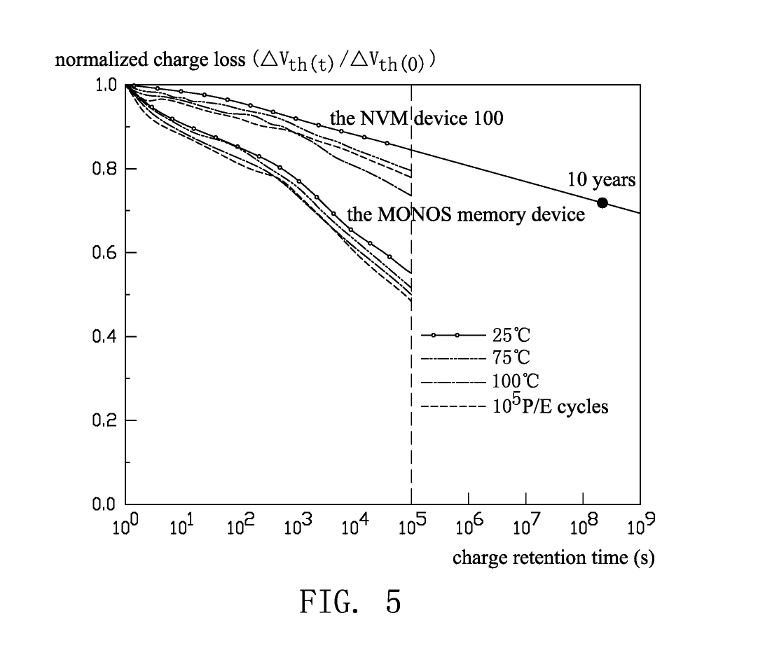

FIG. 5 is a curve diagram illustrating normalized charge loss-charge retention time relationship of the MONOS memory device and a NVM device 100, in accordance with one embodiment of the present invention. The X-axis indicates the charge retention time (s); the Y-axis indicates the normalized charge loss which is defined as ΔVₜₕ₍ₜ₎/ΔV_{th( )}, wherein ΔVₜₕ₍ₜ₎ and ΔV_{th( )} respectively stand for the transient memory window and initial memory window; and different curves indicate the data retention characteristics of the MONOS memory device and the NVM device 100 performed under temperatures of 25° C., 75° C., and 125° C. and after 10⁵ programming/erasing (P/E) cycles.

In accordance with FIG. 5, the NVM device 100 shows superior data retention at room temperature with the charge loss rate of 28.4% in comprising with the MONOS memory device with charge loss rate of 81.7% by extrapolation at ten years. This demonstrates that the quantum dots 106 embedded in the charge trapping layer 105 can enhance the data retention characteristics of the NVM device 100.

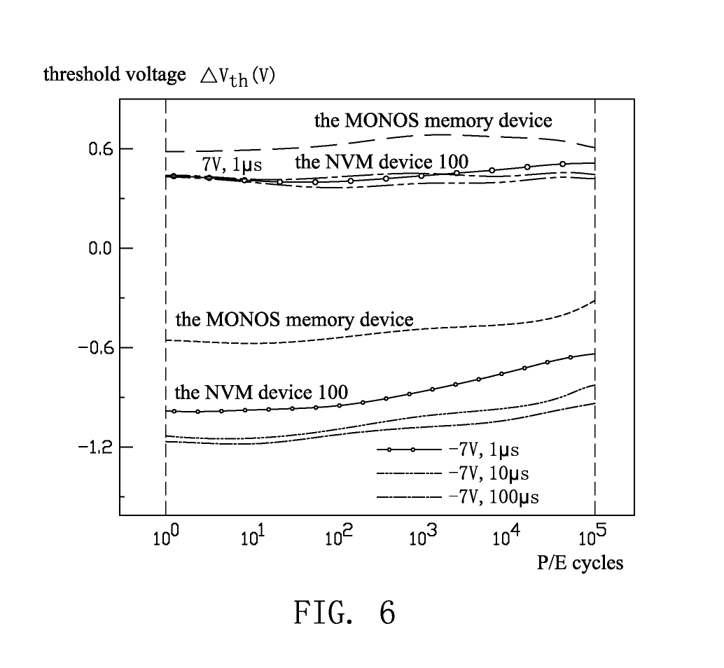

FIG. 6 is a curve diagram illustrating threshold voltage-P/E cycles relationship of the MONOS memory device and the NVM device 100, in accordance with one embodiment of the present invention. The X-axis indicates the P/E cycles; the Y-axis indicates the threshold voltage (ΔVₜₕ) respectively stand for the transient memory window and initial memory window; and different curves indicate the threshold voltage (ΔVₜₕ) variations of the MONOS memory device and the NVM device 100 after 10⁵ P/E cycles at 7 and −7V with 1 μs pulse.

In accordance with FIG. 6, after 10⁵ P/E cycles, the memory window of the NVM device 100 remained broader than that of the MONOS memory device. This demonstrates that the NVM device 100 having the quantum dots 106 embedded therein has superior operation reliability.

In accordance with the aforementioned embodiments, a memory device and a method for fabricating the same are provided, wherein the memory device comprises a stacked structure including a metal gate, a block oxide layer, a charge trapping layer, a tunnel oxide layer and a channel as well as a plurality of conductive quantum dots embedded in the charge trapping layer structure. In addition the memory device further comprises a source/drain structure formed in the substrate and activated by a laser annealing process.

By adopting the quantum dots in the memory device, superior electric characteristics, such as increased P/E speed, decreased operation voltage and the improved reliability, can be provided. In addition, using the laser annealing process to activate the source/drain structure can result in a low thermal budget for fabricating the memory device. Furthermore, the metal gate can shield the stacked structure (including a metal gate, a block oxide layer, a charge trapping layer, a tunnel oxide layer and a channel) from being damaged by the laser, and prevent the quantum dots from re-crystallization or deformation, whereby the performance of the memory device can be improved significantly.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures. For example, in one embodiment of the present invention, the features disclosed in the aforementioned embodiments may be modified and applied for fabricating a three dimensional stacked memory device, an ultra thin channel device, a nano-wire memory device, a carbon-nano-tube memory device or a fin field effect transistor device.

What is claimed is:

1. A memory device comprising:
a substrate;
a tunnel oxide layer, disposed on the substrate and having a thickness substantially less than or equal to 2 nm;
a charge trapping layer, disposed on the tunnel oxide layer
a plurality of conductive quantum dots, embedded in the charge trapping layer;
a block oxide layer, disposed on the charge trapping layer;
a metal gate, essentially consisting of aluminum (Al), copper (Cu), tantalum nitride (TiN), titanium nitride (TaN), aluminum-silicon-copper (Al—Si—Cu) alloys or the arbitrary combinations thereof and disposed on the block oxide layer; and
a source/drain structure, disposed in the substrate.

2. The memory device according to claim 1, wherein the substrate is a silicon substrate or a silicon-on-insulator (SOI) substrate.

3. The memory device according to claim 1, wherein the tunnel oxide layer is a silicon oxide layer and the charge trapping layer is a silicon nitride layer.

4. The memory device according to claim 3, wherein the block oxide layer is a metal oxide layer or a silicon oxide layer.

5. The memory device according to claim 1, wherein the conductive quantum dots are selected from a group consisting of a plurality of semiconductor quantum dots, a plurality of metal quantum dots and the arbitrary combinations thereof.

6. The memory device according to claim 1, wherein the conductive quantum dots are silicon quantum dots having an average particle diameter substantially ranging from 2 nm to 4 nm.

7. The memory device according to claim 1, further comprising:
a channel layer, disposed between the substrate and the tunnel oxide layer; and
an isolation layer, disposed between the substrate and the channel layer.

8. The memory device according to claim 1, wherein the channel layer comprises polycrystalline silicon and the isolation layer is a silicon oxide layer.

9. The memory device according to claim 1, wherein the memory device is a three dimensional stacked memory device, an ultra thin channel device, a nano-wire memory device, a carbon-nano-tube memory device or a fin field effect transistor device.

10. A memory device comprising:
a substrate;
a tunnel oxide layer, disposed on the substrate and having a thickness substantially less than or equal to 2 nm;
a charge trapping layer, disposed on the tunnel oxide layer
a plurality of conductive quantum dots, embedded in the charge trapping layer;
a block oxide layer, disposed on the charge trapping layer;
a metal gate, essentially consisting of aluminum (Al), copper (Cu), aluminum-silicon-copper (Al—Si—Cu) alloys or the arbitrary combinations thereof and disposed on the block oxide layer; and
a source/drain structure, disposed in the substrate.

11. The memory device according to claim 10, wherein the tunnel oxide layer is a silicon oxide layer and the charge trapping layer is a silicon nitride layer.

12. The memory device according to claim 11, wherein the block oxide layer is a metal oxide layer or a silicon oxide layer.

13. The memory device according to claim 10, wherein the conductive quantum dots are selected from a group consisting of a plurality of semiconductor quantum dots, a plurality of metal quantum dots and the arbitrary combinations thereof.

14. The memory device according to claim 10, wherein the conductive quantum dots are silicon quantum dots having an average particle diameter substantially ranging from 2 nm to 4 nm.

15. The memory device according to claim 10, wherein the memory device is a three dimensional stacked memory device, an ultra thin channel device, a nano-wire memory device, a carbon-nano-tube memory device or a fin field effect transistor device

16. A memory device comprising:
a substrate;
a tunnel oxide layer, disposed on the substrate;
a charge trapping layer, disposed on the tunnel oxide layer
a plurality of conductive quantum dots, embedded in the charge trapping layer;
a block oxide layer, disposed on the charge trapping layer;
a metal gate, essentially consisting of aluminum (Al), copper (Cu), aluminum-silicon-copper (Al—Si—Cu) alloys or the arbitrary combinations thereof and disposed on the block oxide layer; and
a source/drain structure, disposed in the substrate.

17. The memory device according to claim 16, wherein the tunnel oxide layer is a silicon oxide layer and the charge trapping layer is a silicon nitride layer.

18. The memory device according to claim 17, wherein the block oxide layer is a metal oxide layer or a silicon oxide layer.

19. The memory device according to claim 16, wherein the conductive quantum dots are selected from a group consisting of a plurality of semiconductor quantum dots, a plurality of metal quantum dots and the arbitrary combinations thereof.

20. The memory device according to claim 16, wherein the conductive quantum dots are silicon quantum dots having an average particle diameter substantially ranging from 2 nm to 4 nm.
